(19) United States
(12) Patent Application Publication
(10) Pub. No.: US 2009/0190287 A1
(43) Pub. Date: Jul. 30, 2009

(54) SOLID ELECTROLYTIC CAPACITOR AND MANUFACTURING METHOD THEREOF

(75) Inventors: Kazuhiro TAKATANI, Amagasaki City (JP); Kazuhito Kikuchi, Hirakata City (JP); Mutsumi Yano, Hirakata City (JP); Takashi Umemoto, Hirakata City (JP); Hiroshi Nonoue, Hirakata City (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi City (JP)

(21) Appl. No.: 12/359,890

(22) Filed: Jan. 26, 2009

(30) Foreign Application Priority Data
Jan. 29, 2008 (JP) JP2008-17605

(51) Int. Cl. H01G 9/042; H01L 21/00

(52) U.S. Cl. 361/529; 29/25.03

(57) ABSTRACT

A solid electrolytic capacitor in which the withstand voltage can be enhanced and a manufacturing method thereof are provided. A mixed powder is prepared by mixing a first powder containing at least one selected from the group consisting of a valve metal, an alloy of a valve metal, a metal oxide of a valve metal, and a metal nitride of a valve metal and a second powder containing a metal oxide different from the first powder. An anode is made by sintering the mixed powder. A dielectric layer is formed on a surface of the anode, and a cathode is formed on the dielectric layer.

### CROSS REFERENCE TO RELATED APPLICATIONS

This application claims priority based on 35 USC 119 from prior Japanese Patent Application No. P2008-17605 filed on Jan. 29, 2008, entitled “Solid Electrolytic Capacitor and Manufacturing Method Thereof”, the entire contents of which are incorporated herein by reference.

### BACKGROUND OF THE INVENTION

1. Field of the Invention

The present invention relates to a solid electrolytic capacitor and a manufacturing method thereof.

2. Description of Related Art

Having a large capacitance and a small equivalent series resistance (ESR), a solid electrolytic capacitor using tantalum or niobium as an anode has been recently widely used as a power source in a personal computer (PC), a game instrument, and the like.

However, since the solid electrolytic capacitor has a low withstand voltage, compared to an aluminum electrolytic capacitor, the application for vehicle installation is problematic. It is generally believed that the low withstand voltage of the solid electrolytic capacitor is due to a defect (crystalline oxide) generated in a dielectric oxide film during anodization.

Japanese Patent Application Publication No. 2002-25864 and Japanese Patent Translation Publication No. 2003-535981 propose that a niobium powder or a niobium-vanadium alloy containing antimony is used as an anode in order to reduce leakage current.

However, even by employing such techniques, it is impossible to sufficiently improve the withstand voltage.

### SUMMARY OF THE INVENTION

An aspect of the invention provides a solid electrolytic capacitor that comprises: an anode, the anode containing a porous sintered body obtained by sintering a mixed powder of a first powder and a second powder, the first powder being made of at least one selected from the group consisting of a valve metal, an alloy of a valve metal, a metal oxide of a valve metal, and a metal nitride of a valve metal, the second powder being made of a metal oxide different from the first powder; a dielectric layer formed on a surface of the anode; and a cathode formed on the dielectric layer.

By using the porous sintered body obtained by sintering the mixed powder of the first powder and the second powder as an anode, a solid electrolytic capacitor having excellent withstand voltage characteristics can be achieved. The reason for the improvement in the withstand voltage characteristics has not been revealed in detail. However, it is assumed that, by using a porous sintered body obtained by sintering after adding the second powder as an anode in accordance with the present invention, generation of a defect in the dielectric layer can be prevented when the dielectric layer is formed on a surface of the anode.

Here, the first powder is not particularly limited as long as the first powder is at least one selected from the group consisting of a valve metal, an alloy of a valve metal, a metal oxide of a valve metal, and a metal nitride of a valve metal. As a preferred first powder, at least one selected from tantalum, niobium, titanium, a tantalum alloy, a niobium alloy, a tantalum nitride, a niobium nitride, and a niobium oxide can be cited. By using these powders, a solid electrolytic capacitor having better withstand voltage characteristics can be obtained.

The second powder is not particularly limited as long as the second powder is a metal oxide powder different from the first powder. As a preferred second powder, at least one selected from vanadium oxide, antimony oxide, gallium oxide, and germanium oxide can be cited. By using these powders, a solid electrolytic capacitor having better withstand voltage characteristics can be obtained.

It is preferable that the melting point of the second powder be lower than the melting point of the first powder. The melting point of the second powder is preferably 2000° C. or lower, more preferably 1200° C. or lower, and further preferably 800° C. or lower. A lower limit value for the melting point is not particularly limited.

It is preferable that the second powder be contained in the anode at a concentration in a range from 1 ppm to less than 1000 ppm relative to a total amount of the first powder and the second powder. If the content of the second powder is outside this range, an effect of preventing a defect in the dielectric layer can not be sufficiently obtained, and, as a result, the withstand voltage characteristics may not be fully improved. A further preferred content of the second powder is in a range from 20 ppm to less than 500 ppm relative to a total amount of the first powder and the second powder.

Another aspect of the invention provides a solid electrolytic capacitor that comprises: an anode, the anode containing a porous sintered body in which a second material is attached to a surface of a first material, the first material being made of at least one selected from the group consisting of a valve metal, an alloy of a valve metal, a metal oxide of a valve metal, and a metal nitride of a valve metal, the second material being made of a metal oxide different from the first material; a dielectric layer formed on a surface of the anode; and a cathode formed on the dielectric layer.

By using the porous sintered body in which the second material exists in the form of being attached to a surface of the first material, in a similar manner as described above, generation of a defect when the dielectric layer is formed can be prevented, and a solid electrolytic capacitor having excellent withstand voltage characteristics can be achieved.

The porous sintered body in which the second material exists in the form of being attached to a surface of the first material can be obtained as described above by sintering a mixed powder of the first powder and the second powder.

As the first material, similar ones to those for the above-mentioned first powder can be cited. As the second material, similar ones to those for the above-mentioned second powder can be cited.

Another aspect of the invention provides a manufacturing method of a solid electrolytic capacitor that comprises the steps of: preparing a mixed powder by mixing a first powder and a second powder, the first powder being made of at least one selected from the group consisting of a valve metal, an alloy of a valve metal, a metal oxide of a valve metal, and a metal nitride of a valve metal, the second powder being made of a metal oxide different from the first powder; forming a dielectric layer on a surface of the anode; and forming a cathode on the dielectric layer.

The temperature of sintering the mixed powder is preferably in a range from 1150° C. to less than 1500° C., and more preferably in a range from 1150° C. to less than 1450° C. If the sintering temperature is outside this range, an effect of improving the withstand voltage characteristics may not be sufficiently obtained.

### BRIEF DESCRIPTION OF THE DRAWING

FIG. 1 illustrates a schematic cross section illustrating a solid electrolytic capacitor according to an embodiment.

### DETAILED DESCRIPTION OF EMBODIMENTS

A solid electrolytic capacitor and a manufacturing method thereof according to embodiments of the present invention are described in more detail. However, the present invention is not limited to the following embodiments and can be appropriately changed without departing from spirit and scope of the invention.

Prepositions, such as “on”, “over” and “above” may be defined with respect to a surface, for example a layer surface, regardless of that surface's orientation in space. The preposition “above” may be used in the specification and claims even if a layer is in contact with another layer. The preposition “on” may be used in the specification and claims when a layer is not in contact with another layer, for example, when there is an intervening layer between them.

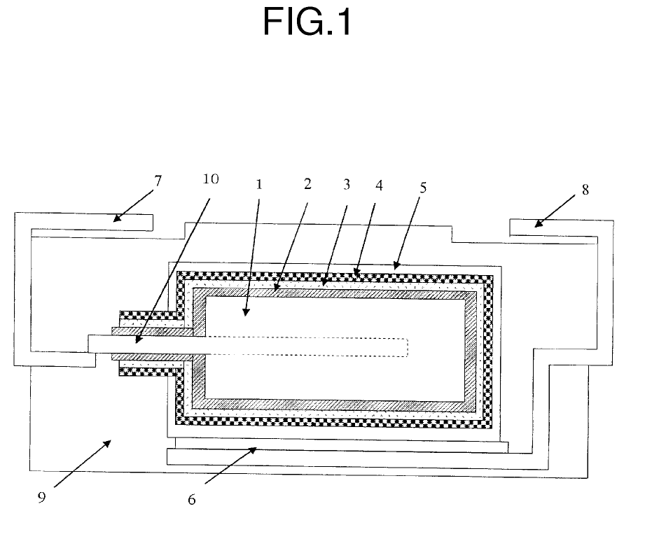

FIG. 1 is a schematic cross sectional view illustrating a solid electrolytic capacitor according to an embodiment. As illustrated in FIG. 1, anode lead 10 is embedded into anode 1. Anode 1 is formed from a mixed powder of a first powder and a second powder, and anode 1 in which anode lead 10 is embedded is prepared by press molding and then sintering the mixed powder having anode lead 10 embedded therein. Accordingly, anode 1 is formed from a porous sintered body obtained by sintering a mixed powder of the first powder and the second powder.

On a surface of anode 1, dielectric layer 2 is formed. Dielectric layer 2 can be formed by anodizing a surface of anode 1. Since anode 1 is a porous sintered body as described above, dielectric layer 2 is also formed on an inside surface of anode 1.

On dielectric layer 2, conductive polymer layer 3 is formed. Conductive polymer layer 3 is also formed inside of anode 1. Conductive polymer layer 3 can be formed by electrolytic polymerization or the like. Conductive polymer layer 3 can be formed from conductive polymer, such as polypyrrole and polythiophene.

On conductive polymer layer 3 on an outer circumferential surface of anode 1, carbon layer 4 and silver paste layer 5 are formed in this order. Carbon layer 4 can be formed by applying and then drying carbon paste. Silver paste layer 5 can be formed by applying and then drying silver paste containing silver particles, a bonding agent, and organic solvent mixed therein.

To silver layer 5, cathode terminal 8 is connected through conductive adhesive agent layer 6. To anode lead 10, anode terminal 7 is connected. Mold resin 9 is formed so that end parts of anode terminal 7 and cathode terminal 8 can be guided to the outside.

Anode 1 of the embodiment is obtained by sintering a mixed powder of the first powder and the second powder, and has high withstand voltage characteristics.

Hereinafter, the various embodiments are described with reference to concrete examples. However, the present invention is not limited by the following examples, and can be modified and implemented accordingly within a range not changing the gist thereof.

### EXAMPLE 1

### [Step 1]

To 0.9998 g of a niobium powder having an average particle size of 2 μm, 2×10⁻⁴ g of a vanadium (V) oxide powder having an average particle size of 1 μm is added and uniformly mixed to prepare a mixed powder. The mixed powder in a state of having a lead wire made of niobium embedded therein is press molded to prepare a molded pellet. The molded pellet is sintered by heating at 1300° C. for 20 minutes in a vacuum (3×10⁻⁵ Torr) to prepare a porous sintered body. The porous sintered body is a sintering body, as described below, in which vanadium oxide exists in the form of being attached to a surface of a porous sintered body made of niobium.

### [Step 2]

By using the sintered body prepared by Step 1 as an anode, a dielectric layer is formed on a surface of the anode by anodizing the anode at a constant voltage of approximately 20 V for approximately 10 hours in a phosphoric acid solution of 0.1% by weight at approximately 60° C.

Next, a polypyrrole layer, which is conductive polymer, is formed by electrolytic polymerization or the like on a surface of the dielectric layer to obtain a conductive polymer layer.

On the surface of the anode on which the conductive polymer layer is formed, carbon paste is applied and dried to form a carbon layer. Next, on the carbon layer, silver paste is applied and dried to form a silver paste layer.

Next, while a cathode terminal is connected to the silver paste layer through the conductive adhesive agent layer, an anode terminal is connected to an anode lead by resistance welding.

Next, a mold resin is formed by coating an exterior resin made of an epoxy resin, and capacitor A1 is prepared.

### [Analysis of Vanadium Oxide]

A cross-sectional surface of the niobium sintered body prepared in Step 1 is analyzed by electron probe microanalyzer (EPMA). As a result, it is revealed that the sintered body is formed by niobium, and vanadium oxide is attached to a surface of niobium.

Furthermore, in order to measure the content of the metal oxide constituting the second powder, the niobium sintered body prepared in Step 1 is dissolved into a hydrofluoric acid solution, and quantitative analysis is conducted by high-frequency inductively-coupled plasma (ICP) analysis. As a result, it is found that 200 ppm of vanadium oxide is contained relative to a total amount of niobium and vanadium oxide.

### EXAMPLE 2

In the same manner as in Example 1, except that a niobium-aluminum alloy powder (aluminum content of approximately 0.5% by weight) having an average particle size of approximately 2 μm is used instead of using a niobium powder, an anode is prepared and capacitor A2 is prepared using the anode.

It is found that vanadium oxide exists in the form of being attached to the surface in the same manner as in Example 1, and its content is 200 ppm relative to a total amount of the first powder and the second powder.

### EXAMPLE 3

In the same manner as in Example 1, except that a niobium nitride powder (nitride content of approximately 500 ppm) having an average particle size of approximately 2 μm is used instead of using a niobium powder, an anode is prepared and capacitor A3 is prepared using the anode.

It is found that vanadium oxide exists in the form of being attached to the surface in the same manner as in Example 1, and its content is 200 ppm relative to a total amount of the first powder and the second powder.

### EXAMPLE 4

In the same manner as in Example 1, except that a tantalum powder having an average particle size of approximately 2 μm is used instead of using a niobium powder, an anode is prepared and capacitor A4 is prepared using the anode.

It is found that vanadium oxide exists in the form of being attached to the surface in the same manner as in Example 1, and its content is 200 ppm relative to a total amount of the first powder and the second powder.

### EXAMPLE 5

In the same manner as in Example 1, except that a tantalum-aluminum alloy powder (aluminum content of approximately 0.5% by weight) having an average particle size of approximately 2 μm is used instead of using a niobium powder, an anode is prepared and capacitor A5 is prepared using the anode.

It is found that vanadium oxide exists in the form of being attached to the surface in the same manner as in Example 1, and its content is 200 ppm relative to a total amount of the first powder and the second powder.

### EXAMPLE 6

In the same manner as in Example 1, except that a tantalum nitride powder (nitride content of approximately 500 ppm) having an average particle size of approximately 2 μm is used instead of using a niobium powder, an anode is prepared and capacitor A6 is prepared using the anode.

It is found that vanadium oxide exists in the form of being attached to the surface in the same manner as in Example 1, and its content is 200 ppm relative to a total amount of the first powder and the second powder.

### EXAMPLE 7

In the same manner as in Example 1, except that a niobium oxide powder having an average particle size of approximately 2 μm is used instead of using a niobium powder, an anode is prepared and capacitor A7 is prepared using the anode.

It is found that vanadium oxide exists in the form of being attached to the surface in the same manner as in Example 1, and its content is 200 ppm relative to a total amount of the first powder and the second powder.

### EXAMPLE 8

In the same manner as in Example 1, except that a titanium powder having an average particle size of approximately 2 μm is used instead of using a niobium powder, an anode is prepared and capacitor A8 is prepared using the anode.

It is found that vanadium oxide exists in the form of being attached to the surface in the same manner as in Example 1, and its content is 200 ppm relative to a total amount of the first powder and the second powder.

### COMPARATIVE EXAMPLE 1

An anode is prepared without adding a vanadium (V) oxide powder in Step 1 in Example 1, and capacitor X1 is prepared using the anode in the same manner as in Example 1.

### COMPARATIVE EXAMPLE 2

An anode is prepared without adding a vanadium (V) oxide powder in Example 4, and capacitor X2 is prepared using the anode in the same manner as in Example 4.

### COMPARATIVE EXAMPLE 3

An anode is prepared without adding a vanadium (V) oxide powder in Example 7, and capacitor X3 is prepared using the anode in the same manner as in Example 7.

### COMPARATIVE EXAMPLE 4

An anode is prepared without adding a vanadium (V) oxide powder in Example 6, and capacitor X4 is prepared using the anode in the same manner as in Example 6.

### COMPARATIVE EXAMPLE 5

An anode is prepared without adding a vanadium (V) oxide powder in Example 8, and capacitor X5 is prepared using the anode in the same manner as that in Example 8.

### COMPARATIVE EXAMPLE 6

An anode is prepared using an antimony powder having an average particle size of approximately 1 μm instead of using a vanadium (V) oxide powder in Step 1 in Example 1, and capacitor X6 is prepared using the anode in the same manner as in Example 1.

### COMPARATIVE EXAMPLE 7

An anode is prepared using a niobium-vanadium alloy powder (vanadium content of approximately 200 ppm) having an average particle size of approximately 2 μm instead of using a niobium powder and a vanadium (V) oxide powder in Step 1 in Example 1, and capacitor X7 is prepared using the anode in the same manner as in Example 1.

### [Measurement of Withstand Voltage]

Regarding the respective capacitors of the above-described examples and comparative examples, the withstand voltage is measured by measuring leakage current while changing applied voltage.

As for leakage current, voltage is applied to a solid electrolytic capacitor while increasing the voltage from 2.5 V by 0.5 V, and a current value 20 seconds after a predetermined voltage is applied is measured.

An applied voltage providing a leakage current five times higher than a leakage current value at an applied voltage of 2.5 V is defined as a withstand voltage.

The measurement results are shown in Table 1.

Note that, in Table 1, content of the second powder, a melting point of the second powder and a sintering temperature for manufacturing an anode are also shown.

TABLE 1

| | | | Content | Melting | | |
|---|---|---|---|---|---|---|
| | | | of | point of | | |
| | | | second | second | Sintering | Withstand |
| | | Second | powder | powder | temperature | voltage |
| | First powder | powder | (ppm) | (° C.) | (° C.) | (V) |
| Capacitor A1 | niobium | vanadium (V) | 200 | 690 | 1300 | 14 |
| | | oxide | | | | |
| Capacitor A2 | niobium | vanadium (V) | 200 | 690 | 1300 | 15 |
| | alloy | oxide | | | | |
| Capacitor A3 | niobium | vanadium (V) | 200 | 690 | 1300 | 14 |
| | nitride | oxide | | | | |
| Capacitor A4 | tantalum | vanadium (V) | 200 | 690 | 1300 | 17 |
| | | oxide | | | | |
| Capacitor A5 | tantalum | vanadium (V) | 200 | 690 | 1300 | 17 |
| | alloy | oxide | | | | |
| Capacitor A6 | tantalum | vanadium (V) | 200 | 690 | 1300 | 17 |
| | nitride | oxide | | | | |
| Capacitor A7 | niobium | vanadium (V) | 200 | 690 | 1300 | 14 |
| | oxide | oxide | | | | |
| Capacitor A8 | titanium | vanadium (V) | 200 | 690 | 1300 | 6 |
| | | oxide | | | | |
| Capacitor X1 | niobium | — | — | — | 1300 | 8 |
| Capacitor X2 | tantalum | — | — | — | 1300 | 11 |
| Capacitor X3 | niobium | — | — | — | 1300 | 8 |
| | oxide | | | | | |
| Capacitor X4 | tantalum | — | — | — | 1300 | 11 |
| | nitride | | | | | |
| Capacitor X5 | titanium | — | — | — | 1300 | 4 |
| Capacitor X6 | niobium | antimony | 200 | 630 | 1300 | 8 |
| Capacitor X7 | niobium- | — | — | — | 1300 | 8 |
| | vanadium | | | | | |
| | alloy | | | | | |

As shown in Table 1, it is observed that capacitors A1 to A7 using an anode obtained by sintering a mixture of the first powder and the second powder in accordance with Examples have a high withstand voltage compared to capacitors X1 to X4 for comparison. Furthermore, capacitor A8 using titanium as the first powder has a low withstand voltage compared to those of capacitors A1 to A7, since the withstand voltage of titanium oxide serving as a dielectric body is originally low. However, a high withstand voltage is attained compared to capacitor X5 for comparison which uses titanium as a valve metal.

Capacitor X6 for comparison uses an anode obtained by sintering niobium added with antimony, and capacitor X7 for comparison uses an anode made of a niobium-vanadium alloy. However, it is observed that the withstand voltage is not improved.

### EXAMPLE 9 TO 16

Here, the kind of the second powder is investigated.

Anodes are prepared in Step 1 in Example 1 using an antimony (III) oxide powder having an average particle size of approximately 1 μm, a gallium (III) oxide powder having an average particle size of approximately 1 μm, a germanium (IV) oxide powder having an average particle size of approximately 1 μm, and a nickel oxide powder having an average particle size of approximately 1 μm instead of using a vanadium (V) oxide powder, and capacitors B1 to B4 are prepared using the obtained anodes in the same manner as in Example 1.

Furthermore, an anode is prepared in the same manner as in Example 1 except that 1×10⁻⁴ g of an antimony (III) oxide powder and 1×10⁻⁴ g of a vanadium (V) oxide powder are used instead of using a vanadium (V) oxide powder in Step 1 in Example 1, and capacitor B5 is prepared using the obtained anode.

Furthermore, an anode is prepared in the same manner as in Example 2 except that an antimony (III) oxide powder having an average particle size of approximately 1 μm is used instead of using a vanadium (V) oxide powder in Example 2, and capacitor B6 is prepared using the obtained anode.

Furthermore, an anode is prepared in the same manner as in Example 3 except that an antimony (III) oxide powder having an average particle size of approximately 1 μm is used instead of using a vanadium (V) oxide powder in Example 3, and capacitor B7 is prepared using the obtained anode.

Furthermore, an anode is prepared in the same manner as in Example 4 except that a germanium (IV) oxide powder having an average particle size of approximately 1 μm is used instead of using a vanadium (V) oxide powder in Example 4, and capacitor B8 is prepared using the obtained anode.

Content of the second powder is measured by the same manner as described above.

Regarding capacitors B1 to B8, the withstand voltage is measured in the same manner as described above, and the measurement results are shown in Table 2.

TABLE 2

| | | | | Melting | | |
|---|---|---|---|---|---|---|
| | | | Content | point of | | |
| | | | of second | second | Sintering | Withstand |
| | First | | powder | powder | temperature | voltage |
| | powder | Second powder | (ppm) | (° C.) | (° C.) | (V) |
| Capacitor | niobium | antimony (III) | 200 | 656 | 1300 | 15 |
| B1 | | oxide | | | | |
| Capacitor | niobium | gallium (III) | 200 | 600 | 1300 | 13 |
| B2 | | oxide | | | | |
| Capacitor | niobium | germanium (IV) | 200 | 1116 | 1300 | 13 |
| B3 | | oxide | | | | |
| Capacitor | niobium | nickel (II) | 200 | 1960 | 1300 | 10 |
| B4 | | oxide | | | | |
| Capacitor | niobium | antimony (III) | 100 | 656 | | |
| B5 | | oxide | | | | |
| | | vanadium (V) | 100 | 690 | 1300 | 16 |
| | | oxide | | | | |
| Capacitor | niobium | antimony (III) | 200 | 656 | 1300 | 16 |
| B6 | alloy | oxide | | | | |
| Capacitor | niobium | antimony (III) | 200 | 656 | 1300 | 15 |
| B7 | nitride | oxide | | | | |
| Capacitor | tantalum | germanium (IV) | 200 | 1116 | 1300 | 18 |
| B8 | | oxide | | | | |

As apparent from the results shown in Table 2, in the case of using antimony (III) oxide, gallium (III) oxide, germanium (IV) oxide, or nickel (II) oxide as the second powder, high withstand voltage characteristics can also be obtained. Especially, in the case of using antimony oxide, gallium oxide, of germanium oxide, a high withstand voltage is attained.

### EXAMPLES 17 TO 29

Here, the relationship between the content of the second powder and a leakage current is investigated.

In Step 1 in Example 1, a niobium powder and a vanadium oxide powder are mixed at the following ratios.

Niobium powder: vanadium oxide powder in the respective examples

| | | | |
|---|---|---|---|
| Example 17: | 0.9999995 | g | 5 × 10⁻⁷ g |
| Example 18: | 0.99999925 | g | 7.5 × 10⁻⁷ g |
| Example 19: | 0.999999 | g | 1 × 10⁻⁶ g |
| Example 20: | 0.999995 | g | 5 × 10⁻⁶ g |
| Example 21: | 0.99999 | g | 1 × 10⁻⁵ g |
| Example 22: | 0.99998 | g | 2 × 10⁻⁵ g |
| Example 23: | 0.99995 | g | 5 × 10⁻⁵ g |
| Example 24: | 0.9999 | g | 1 × 10⁻⁴ g |
| Example 25: | 0.9996 | g | 4 × 10⁻⁴ g |
| Example 26: | 0.9995 | g | 5 × 10⁻⁴ g |
| Example 27: | 0.9991 | g | 9 × 10⁻⁴ g |
| Example 28: | 0.999 | g | 1 × 10⁻³ g |
| Example 29: | 0.9988 | g | 1.2 × 10⁻³ g |

The content of vanadium oxide in the anodes respectively prepared as described above is measured in the same manner as described above. The content of vanadium oxide in the respective examples is as follows.

| | | |
|---|---|---|
| Example 17: | 0.5 | ppm |
| Example 18: | 0.75 | ppm |
| Example 19: | 1 | ppm |
| Example 20: | 5 | ppm |
| Example 21: | 10 | ppm |
| Example 22: | 20 | ppm |
| Example 23: | 50 | ppm |
| Example 24: | 100 | ppm |
| Example 25: | 400 | ppm |
| Example 26: | 500 | ppm |
| Example 27: | 900 | ppm |
| Example 28: | 1000 | ppm |
| Example 29: | 1200 | ppm |

Capacitors C1 to C13 are prepared in the same manner as that in Example 1 except for using the respective anodes prepared as described above. The withstand voltage of each of the capacitors is measured in the same manner as described above. The measurement results are shown in Table 3.

Note that, in Table 3, the values of capacitor A1 are also shown.

TABLE 3

| | | | Content of | |
|---|---|---|---|---|
| | | | second | Withstand |
| | First | | powder | voltage |
| | powder | Second powder | (ppm) | (V) |
| Capacitor C1 | niobium | vanadium (V) oxide | 0.5 | 10 |
| Capacitor C2 | niobium | vanadium (V) oxide | 0.75 | 10 |
| Capacitor C3 | niobium | vanadium (V) oxide | 1 | 12 |
| Capacitor C4 | niobium | vanadium (V) oxide | 5 | 12 |
| Capacitor C5 | niobium | vanadium (V) oxide | 10 | 12 |
| Capacitor C6 | niobium | vanadium (V) oxide | 20 | 14 |
| Capacitor C7 | niobium | vanadium (V) oxide | 50 | 14 |
| Capacitor C8 | niobium | vanadium (V) oxide | 100 | 14 |
| Capacitor A1 | niobium | vanadium (V) oxide | 200 | 14 |
| Capacitor C9 | niobium | vanadium (V) oxide | 400 | 14 |
| Capacitor C10 | niobium | vanadium (V) oxide | 500 | 12 |
| Capacitor C11 | niobium | vanadium (V) oxide | 900 | 12 |
| Capacitor C12 | niobium | vanadium (V) oxide | 1000 | 10 |
| Capacitor C13 | niobium | vanadium (V) oxide | 1200 | 10 |

As apparent from the results shown in Table 3, especially good withstand voltage is obtained in capacitors C3 to C11 and capacitor A1 each of which has a content of vanadium oxide relative to a total amount of niobium and vanadium oxide in a range from 1 ppm to less than 1000 ppm. It is also observed that, among these, in capacitors C6 to C9 and capacitor A1 each of which has a content of vanadium oxide in a range from 20 ppm to less than 500 ppm, the withstand voltage is significantly increased.

### EXAMPLES 30 TO 35

Here, the relationship between a sintering temperature when an anode is manufactured by sintering and the withstand voltage is investigated.

Sintered bodies are prepared by sintering a molded pellet in vacuum (3×10⁻⁵ Torr) at a sintering temperature of 1100° C., 1150° C., 1200° C., 1450° C., 1500° C., and 1550° C., respectively, instead of at 1300° C., in Step 1 in Example 1. Capacitors D1 to D6 are each prepared in the same manner as in Example 1 except that the sintering body is used as an anode.

As for the obtained capacitors D1 to D6, the withstand voltage is measured in the same manner as described above. The measurement results are shown in Table 4.

Note that, in Table 4, the values of capacitor A1 are also shown.

TABLE 4

| | | | Content of | |
|---|---|---|---|---|
| | | | second | Withstand |
| | | | powder | voltage |
| | First powder | Second powder | (ppm) | (V) |
| Capacitor D1 | niobium | vanadium (V) oxide | 1100 | 10 |
| Capacitor D2 | niobium | vanadium (V) oxide | 1150 | 13 |
| Capacitor D3 | niobium | vanadium (V) oxide | 1200 | 13 |
| Capacitor A1 | niobium | vanadium (V) oxide | 1300 | 14 |
| Capacitor D4 | niobium | vanadium (V) oxide | 1450 | 14 |
| Capacitor D5 | niobium | vanadium (V) oxide | 1500 | 10 |
| Capacitor D6 | niobium | vanadium (V) oxide | 1550 | 10 |

As apparent from the results shown in Table 4, it is known that an especially high withstand voltage can be obtained by setting a sintering temperature when an anode is prepared to be in a range from 1150° C. to less than 1500° C. The sintering temperature is further preferably in a range from 1150° C. to 1450° C.

As described above, according to the solid electrolytic capacitor and the manufacturing method thereof of the embodiment, it is possible to provide a solid electrolytic capacitor in which the withstand voltage can be enhanced.

What is claimed is:

1. A solid electrolytic capacitor, comprising:
an anode including a porous sintered body obtained by sintering a mixed powder of a first powder and a second powder, the first powder containing at least one selected from the group consisting of a valve metal, an alloy of a valve metal, a metal oxide of a valve metal, and a metal nitride of a valve metal, the second powder containing a metal oxide different from the first powder;
a dielectric layer formed on a surface of the anode; and
a cathode formed on the dielectric layer.

2. The solid electrolytic capacitor of claim 1, wherein the first powder is at least one selected from the group consisting of tantalum, niobium, titanium, a tantalum alloy, a niobium alloy, tantalum nitride, niobium nitride, and niobium oxide.

3. The solid electrolytic capacitor of claim 1, wherein the second powder is at least one selected from the group consisting of vanadium oxide, antimony oxide, gallium oxide, and germanium oxide.

4. The solid electrolytic capacitor of claim 1, wherein a melting point of the second powder is lower than a melting point of the first powder.

5. The solid electrolytic capacitor of claim 1, wherein a melting point of the second powder is no more than 2000° C.

6. The solid electrolytic capacitor of claim 1, wherein a melting point of the second powder is no more than 1200° C.

7. The solid electrolytic capacitor of claim 1, wherein a melting point of the second powder is no more than 800° C.

8. The solid electrolytic capacitor of claim 1, wherein the second powder is contained in the anode at a concentration in a range from 1 ppm to less than 1000 ppm relative to a total amount of the first powder and the second powder.

9. The solid electrolytic capacitor of claim 1, wherein the second powder is contained in the anode at a concentration in a range from 20 ppm to less than 500 ppm relative to a total amount of the first powder and the second powder.

10. A solid electrolytic capacitor, comprising:
an anode including a porous sintered body in which a second material is attached to a surface of a first material, the first material containing of at least one selected from the group consisting of a valve metal, an alloy of a valve metal, a metal oxide of a valve metal, and a metal nitride of a valve metal, the second material containing a metal oxide different from the first material;
a dielectric layer formed on a surface of the anode; and
a cathode formed on the dielectric layer.

11. The solid electrolytic capacitor of claim 10, wherein the first material is at least one selected from the group consisting of tantalum, niobium, titanium, a tantalum alloy, a niobium alloy, tantalum nitride, niobium nitride, and niobium oxide.

12. The solid electrolytic capacitor of claim 10, wherein the second material is at least one selected from the group consisting of vanadium oxide, antimony oxide, gallium oxide, and germanium oxide.

13. The solid electrolytic capacitor of claim 10, wherein a melting point of the second material is lower than a melting point of the first material.

14. The solid electrolytic capacitor of claim 10, wherein the second material is contained in the anode at a concentration in a range from 1 ppm to less than 1000 ppm relative to a total amount of the first material and the second material.

15. The solid electrolytic capacitor of claim 10, wherein the second material is contained in the anode at a concentration in a range from 20 ppm to less than 500 ppm relative to a total amount of the first material and the second material.

16. A manufacturing method of a solid electrolytic capacitor, comprising:
preparing a mixed powder by mixing a first powder and a second powder, the first powder containing at least one selected from the group consisting of a valve metal, an alloy of a valve metal, a metal oxide of a valve metal, and a metal nitride of a valve metal, the second powder containing a metal oxide different from the first powder;
forming an anode by sintering the mixed powder;
forming a dielectric layer on a surface of the anode; and
forming a cathode on the dielectric layer.

17. The manufacturing method of claim 16, wherein a temperature of sintering the mixed powder is in a range from 1150° C. to less than 1500° C.

18. The manufacturing method of claim 16, wherein the first powder is at least one selected from the group consisting of tantalum, niobium, titanium, a tantalum alloy, a niobium alloy, tantalum nitride, niobium nitride, and niobium oxide.

19. The manufacturing method of claim 16, wherein the second powder is at least one selected from the group consisting of vanadium oxide, antimony oxide, gallium oxide, and germanium oxide.

20. The manufacturing method of claim 16, wherein a melting point of the second powder is lower than a melting point of the first powder.
